(19) United States
(12) Patent Application Publication
(10) Pub. No.: US 2013/0002104 A1
(43) Pub. Date: Jan. 3, 2013

(54) STRUCTURE AND A METHOD FOR SUPPRESSING NOISE OF ELECTRONIC EQUIPMENT

(76) Inventor: Huimin Chen, Taoyuan County (TW)

(21) Appl. No.: 13/634,049

(22) PCT Filed: May 9, 2011
(86) PCT No.: PCT/CN2011/073827

§ 371 Date: Sep. 11, 2012

(30) Foreign Application Priority Data
May 10, 2010 (CN) 20101016808013

(51) Int. Cl. H05K 5/03; C04B 35/48

(52) U.S. Cl. 312/223.1; 264/666

(57) ABSTRACT

A structure and a method for suppressing noise of electronic equipment utilize a noise suppresser to cover a periphery or a surface of the electronic equipment or the circuits thereof. The noise suppresser comprises elements of zirconia and at least one oxide that serves as a stabilizer. By compounding afore elements and sintering process the compound, a zirconia ceramics is formed. Simply made and costing less, the noise suppresser yet offers numerous applicable means. The noise around the electronic equipment is efficiently reduced or suppressed while operating. Thereby, the quality of electronic signals transmitted between the circuits of the electronic equipment is enhanced. Further, when the noise suppressor is disposed on a periphery or a surface of the electronic equipment or the circuits thereof, far infrared and resonance are concurrently generated while the electronic equipment is electrified, so that accumulated heat in the electronic equipment is dispersed for reducing noise.

### FIELD OF THE INVENTION

The present invention relates to a structure and a method for suppressing noise of electronic equipment.

### DESCRIPTION OF THE RELATED ART

Recently, digital electronic equipment, such as mobile phones, digital cameras, and laptops, is developed greatly. Herein, afore products generally require operating signals that are of high frequency, small dimension, and light weight. However, since electronic parts or circuit boards are arranged in high density, techniques for developing afore products are in fact difficult.

While the electronic parts or the circuit hoards of the electronic equipment are arranged in the high density, and while the operating signals thereof require a high frequency, a distance between a part that generates noise and other parts of the electronic equipment is hard to be predicted and drawn up. Therefore, a noise suppresser for suppressing emission radiation noise generated by the electronic equipment such as microprocessor, LSI, electronic coupling, or LCD panel, has to be attached to the circuits, the circuit boards, or the electronic couplings. However, if a reflected wave from the noise suppresser is generated too widely, the reflected wave signals of the circuit transmission might be interfered, thereby resulting in errors.

Electronic signals that are transmitted within conventional audio components or devices, such as the player, the amplifier, the loudspeaker, the microphone, the earphone, the mobile communicator, the sound car, the audio frequency apparatus, the electronic video device, and the telecommunication circuit, are easily influenced by external environment. For example, the radio frequency (RF) in the air, the static electricity, the radiation, the noise contained in the transmission circuit, the electronic parts, or the circuits of the electronic equipment commonly have noise and readily generate further noise so as to incur a reduced quality or a distortion on the signals.

Familiarly, the electronic signals in audio equipment are usually processed by the circuits therein. Thereafter, transmission lines help the electronic signals be sent to an external amplifier. During the transmission, the impedance, the capacitance, and the inductance are contained within the internal circuits and the transmission lines, which adversely give off heat. Accordingly, if a suited mechanism for dispersing or reducing the accumulated heat can not be provided, the heat thence makes the transmission of the electronic signals in the circuits become weak. As a result, the distortion and the noise are brought about.

Moreover, the accumulated heat generated in the internal electronic parts or the circuits in view of the external environment allows the electronic signals in the electronic equipment to reduce the output quality in accordance with noise of different magnitude and amounts. Although afore shortcomings could be amended by using transmission lines that are of high conduction and provide a protection of preferred shield, such transmission lines are in fact expensive. Thus, the amendment is not available to all.

### SUMMARY OF THE INVENTION

The object of the present invention is to provide a method for suppressing noise of electronic equipment that applies a noise suppresser with a simple construction and a low expense for preferably reducing or repressing noise in the circuits, thereby enhancing the quality of the electronic equipment or the electronic signals in the circuit transmission.

The method in accordance with the present invention utilizes a zirconia ceramics to cover on an appearance of the electronic equipment. The zirconia ceramics mainly consists of elements of zirconia and at least one oxide. Afore elements are further compounded into a compound material and executed to a sintering process.

The oxide adopts calcium oxide, magnesia, yttrium (III) oxide, or a compound formed by afore elements.

A weight percentage of the zirconia is between 80 and 99%, and a weight percentage of the oxide is between 1 and 20%; wherein, the oxide adopts magnesia, calcium oxide, yttrium (III) oxide, or a compound formed by at least two of afore elements.

The ceramics wrapper adopts a sleeve, a shelter, or a covering that is formed into a flake, a pillar, an acicular formation, powders, a hollow column, or a solid column.

A method for suppressing noise of electronic equipment, wherein, a structure for suppressing noise is used to shield an appearance of the electronic equipment; the structure for suppressing noise of electronic equipment being made by steps of:

preparing a material of zirconia (formed by powder) by a weight percentage of 80 to 99%;

preparing a material of oxide stabilizer (formed by powder) by a weight percentage of 1 to 20%; and

evenly compounding said two materials into a compound material and proceeding to a sintering process for forming the compound material into a zirconia ceramics.

The sintering process sequentially includes a heating stage, a steady temperature stage, and a cooling stage. Wherein, the heating stage heats an operating temperature from a room temperature to a temperature between 1170° C. and 1850° C. The steady temperature stage maintains the operating temperature at a fixed temperature between 1170° C. and 1850° C. for 1 hour to 4 hours. In the cooling stage, the operating temperature is cooled from the temperature between 1170° C. and 1850° C. to a room temperature within 11 to 15 hours. The zirconia ceramics that is sintered is further crumbled into powder. The compound material is pressed before the sintering process for being formed into the sleeve or the shelter.

Accordingly, the present invention provides the following advantages:

1. The structure for suppressing noise of electronic equipment could be conveniently disposed on a periphery or a surface of the electronic equipment for reducing or repressing the noise around the electronic equipment.

2. The structure for suppressing noise of electronic equipment preferably generates far infrared and resonance while the equipment is electrified, thereby increasing the heat conduction efficiency. Whereby, the heat accumulated in the electronic parts and the circuit of the electronic equipment could be dispersed in a short time. Thus, the opportunity that the noise is generated during a signal transmission in view of the accumulated heat in the circuits of the electronic equipment could be reduced or suppressed so as to enhance the signal transmission quality accordingly.

3. The structure for suppressing noise of electronic equipment could be manufactured conveniently with a low cost. Therefore, a wide application could be provided for being suited to the general electronic products in the market.

### DESCRIPTION OF ELEMENTS IN THE DRAWINGS

| | | | |
|---|---|---|---|
| 10, 10A | noise suppresser | 20 | transmission line |
| 30 | circuit board | 31 | connector of inlet port |

| | |
|---|---|
| 32 | connector of outlet port |

### BRIEF DESCRIPTION OF THE DRAWINGS

Following figures give a detail presentation of the present invention:

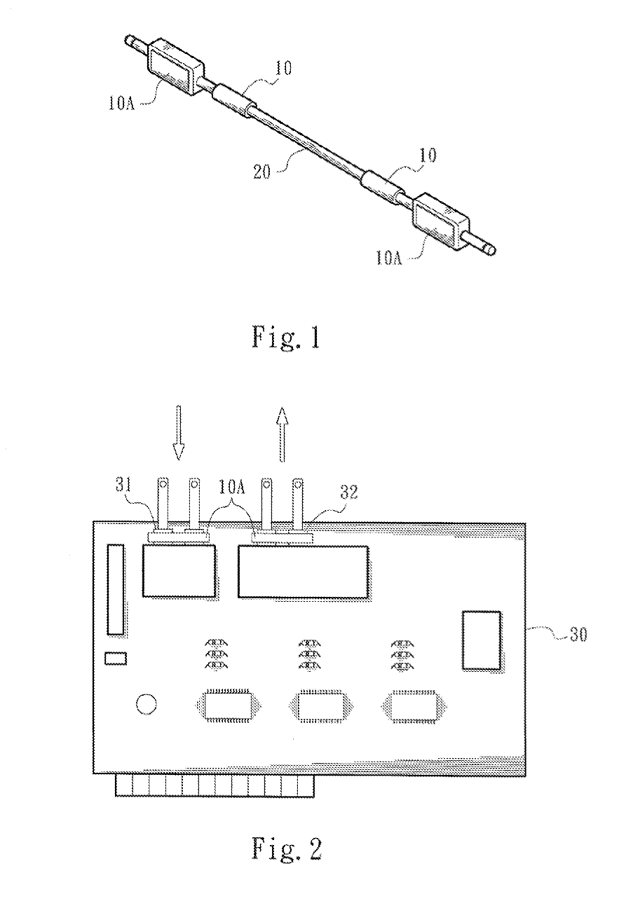

FIG. 1 is a schematic view showing the present invention applied in transmission lines;

FIG. 2 is a schematic view showing the present invention applied in circuit boards;

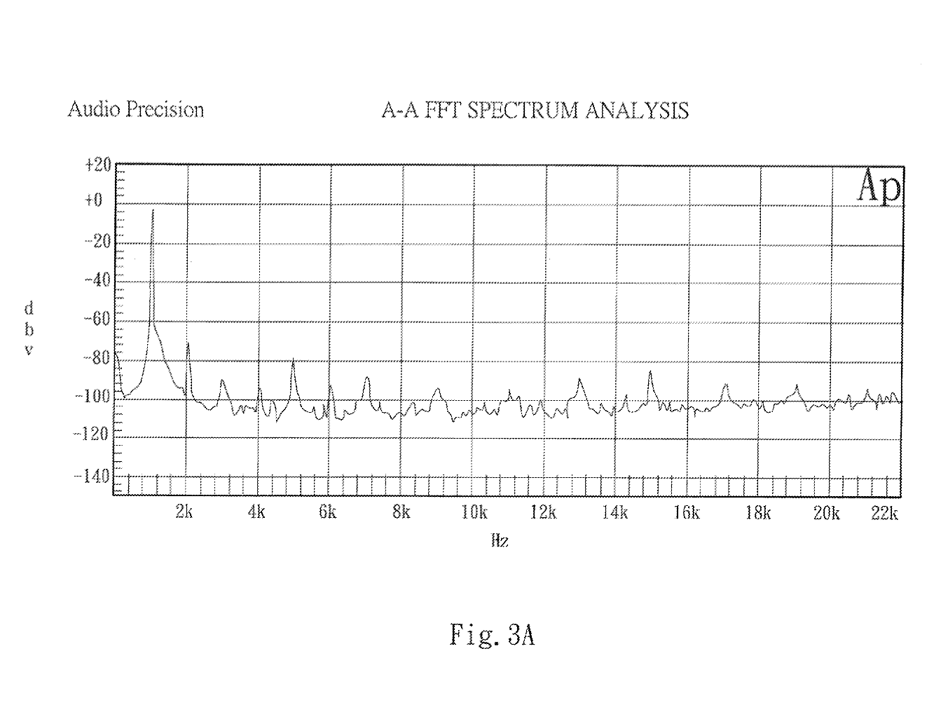

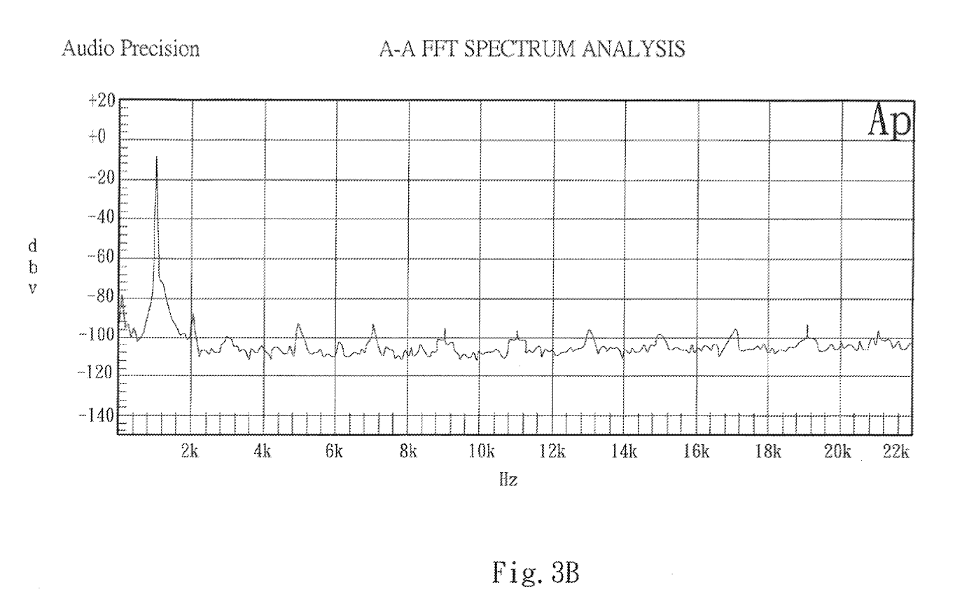

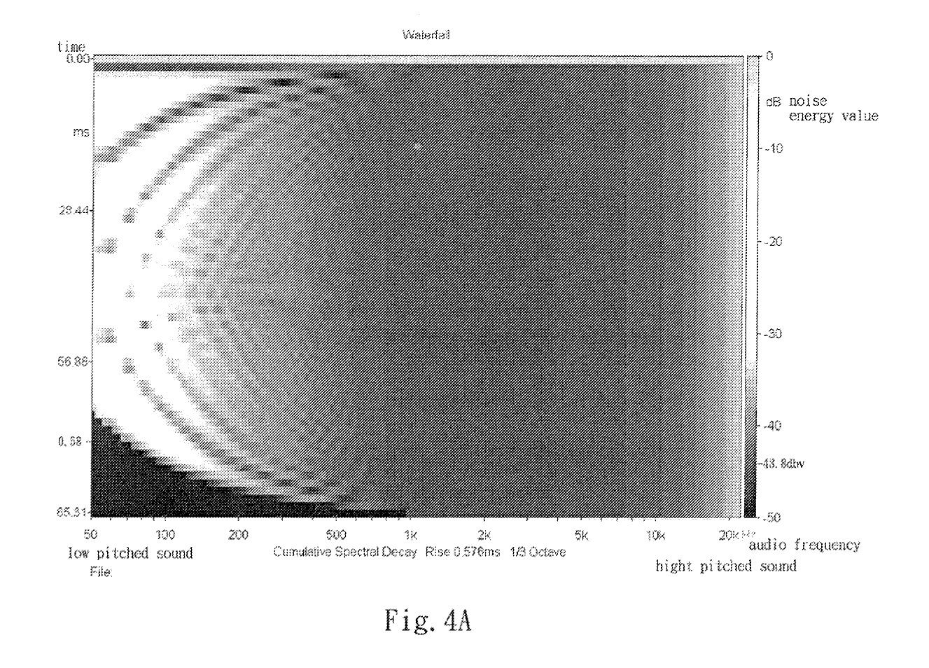

FIG. 3A is an oscillogram showing a test on a suppressing result of the electronic equipment that is unequipped with the structure of the present invention;

FIG. 3B is an oscillogram showing a test on a suppressing result of the electronic equipment that is equipped with the structure of the present invention;

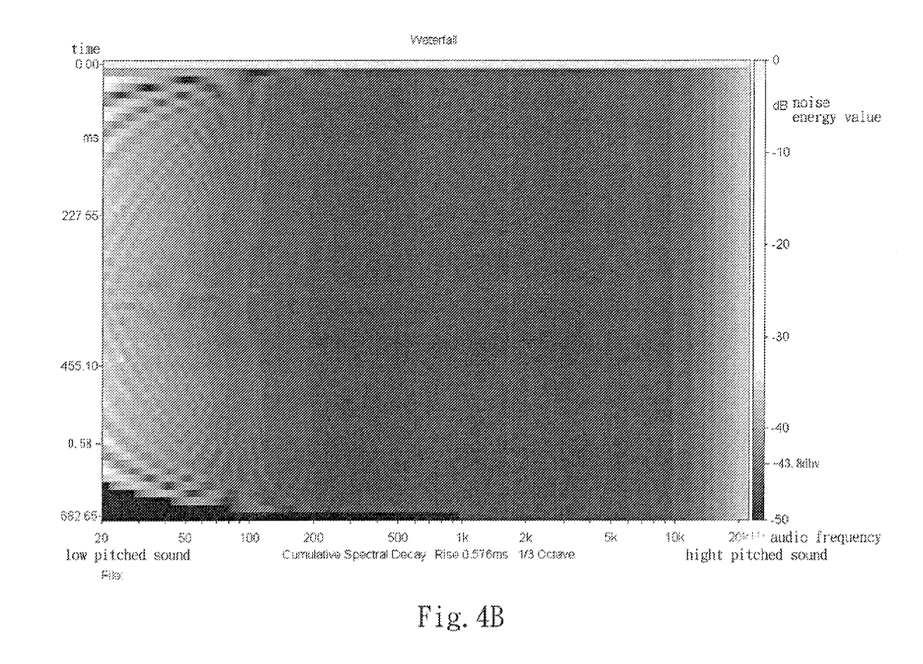

FIG. 4A is a joint analysis on the energy-time-frequency of the electronic equipment that is unequipped with the structure of the present invention; and

FIG. 4B is a joint analysis on the energy-time-frequency of the electronic equipment that is equipped with the structure of the present invention.

### DETAILED DESCRIPTION OF THE PREFERRED EMBODIMENTS

The performances and properties of the present invention could be clearly shown by the following embodiments.

A method for suppressing noise of electronic equipment utilizes a zirconia ceramics to cover an appearance of the electronic equipment. Wherein, the zirconia ceramics consists of zirconia of a certain proportion and other oxide. Whereby, the combination of afore elements is further heated to form the zirconia ceramics. Accordingly, a physical property, such as magnetism or frequency, of the electronic equipment could be changed. When a noise suppresser served by the zirconia ceramics is disposed on a periphery or a surface of the circuits, the noise going by the electronic equipment could be reduced or suppressed. Moreover, the noise suppresser further generates far infrared in time of the electronic equipment being electrified, which promotes the heat dispersion and reduces the noise thereof. Subsequently, the quality of the transmitted electronic signals is preferably enhanced in the circuits of the electronic equipment.

The structure and the method for suppressing noise of electronic equipment in accordance with the present invention could be applied in general circuits (parts including circuit boards and circuits), parts or devices that process or transmit video signals, audio components or devices. For example, the player, the amplifier, the loudspeaker, the microphone, the ear phone, the mobile communicator, the sound card, the audio frequency apparatus, the electronic video device, the circuits of the transmission lines of telecommunication are all applicable. The following embodiments take the audio component as an example for explanation. It should be noted that the processing and the transmission of the audio electronic signals and the video signals are in common. Thus, the noise suppressor that is available for the electronic signals of the audio component is also available for the signals of the video system. Therefore, the similar functions and correlations are omitted.

The noise suppresser in accordance with the present invention comprises zirconia ceramics that mainly consists of zirconia (ZrO2) and yttrium (III) oxide (Y2O3), calcium oxide (CaO), magnesia (MgO), other oxide, or a combination of afore oxide that serves as a stabilizer. The constituent of the present invention is not limited by afore elements. Also, afore listed elements have their distinguishing properties. The noise suppresser is mainly constituted by the following proportions (weight percentage):

First preferred embodiment: zirconia 80 to 99%, magnesia 1 to 20%;

Second preferred embodiment: zirconia 80 to 99%, calcium oxide 1 to 20%;

Third preferred embodiment: zirconia 80 to 99%, yttrium (II) oxide 1 to 20%;

Fourth preferred embodiment: zirconia 80 to 99%, magnesia 1 to 19%, calcium oxide 1 to 19%;

Fifth preferred embodiment: zirconia 80 to 99%, magnesia 1 to 19%, yttrium (III) oxide 1 to 19%;

Sixth preferred embodiment: zirconia 80 to 99%, calcium magnesium oxide 1 to 19%, yttrium (III) oxide 1 to 19%; and

Seventh preferred embodiment: zirconia 80 to 99%, magnesia 1 to 18%, calcium oxide 1 to 18%, yttrium (III) oxide 1 to 18.

The structure for suppressing noise of electronic equipment in accordance with afore embodiments is made as follows:

Firstly, adopt part of afore elements or all of afore elements and evenly compound the same via the certain proportion. Secondly, the compounded elements are pressed into a desired formation (a flake). This pressing could be achieved by a mold or a processor that is able to form the compounded elements into various shapes. According to the practical application, the configuration of the compounded elements could be annular like, flake like (thin flake, curved flake, plain flake are all available), rod like, acicular like, hollow column, solid column, pellet, or other suited geometrical formation. Subsequently, the shaped composition is conveyed to a furnace, such as a tunnel furnace, for conducing to the zirconia ceramics via a sintering process. Thereby, the noise suppresser of the present invention is achieved.

The sintering process sequentially includes a heating stage, a steady temperature stage, and a cooling stage. Wherein, in the heating stage, an operating temperature in the furnace is raised from a room temperature to a temperature between 1170° C. and 1850° C. within 8 to 14 hours. In the steady temperature stage, the operating temperature is maintained at a fixed temperature between 1170° C. and 1850° C. for about 1 to 4 hours. In the cooling stage, the operating temperature is cooled from the temperature between 1170° C. and 1850° C. to the room temperature within 11 to 15 hours. Accordingly, the sintering process is completed.

It should be noted that, the operating temperature between 1170° C. and 1850° C. is the preferred temperature for the sintering process. Namely, in the practical application, the sintering temperature could be freely adjusted. Any temperature is applicable as long as the zirconia and other compound (or other oxides) are well turned into the zirconia ceramics. Wherein, the sintered noise suppresser could directly cover on or attach to the electronic equipment, the circuits, or a periphery of the circuits. While the noise suppresser is formed into the powder, the powder could be applied to the electronic equipment or to the surface of the circuits that need to restrain the noise. While additionally applying the glue or the tape to the powder, the powder becomes sticky and well attached to the apparatus. For example, the surface of the circuits on the circuit boards or the surface of electronic couplings of ports of the circuits could be preferably applied with the sticky powder.

Referring to FIG. 1, the present invention is practically utilized. A noise suppresser 10 is designed into a sleeve or a shelter (like a ring sleeve or a flexible flake) for covering a periphery of a general transmission line 20, As shown in the figure, the sleeve or the shelter is pressed into an annular shape for disposing on ports or a middle part of the transmission line 20. Two ports of the transmission line 20 are respectively connected to a main frame of the electronic equipment (such as a stereo) and an external amplifier or a loudspeaker. Herein, since the ceramic noise suppresser 10 provides resonance or heat dispersion effect while the electronic equipment is electrified, the noise generated near the transmission line 20 in time of uploading electronic signals could be reduced or suppressed. That is, when the noise suppresser 10 is installed on the transmission line 20 connected between the stereo and the amplifier, the electronic signal that is of a smaller signal domain could filter out the noise generated in the audio electronic signal by means of the noise suppresser 10. When the noise suppresser 10 is installed on the transmission line 20 connected between the amplifier and the loudspeaker, the electronic signal processed by the amplifier could preferably filter out noise generated in waves of the electronic signal by means of the noise suppresser 10. Accordingly, the filtered electronic signal could be further sent into the loudspeaker.

Referring to FIG. 2, the noise suppresser 10 is applied to a circuit board 30. Herein, the noise suppressor 10 that is formed into a strip or a flake is fixed on or attached to a connector 31 of an input port and a connector 32 of an output port of the circuit board 30. Accordingly, the noise generated from the electronic signal in the circuit board 30 could be filtered out or restrained. In order to expand the practical application of the noise suppresser 10, the formation there of could adopt a plate, a strip, a flake, or a powder. Afore various formations could be freely adapted to surfaces of integrated circuit, metal coil, and circuit layout on the circuit board 30.

In order to testify that the suppression on the noise is indeed efficient, a comparison between the noise magnitude before applying the present invention and after applying the present invention is provided along with an Audio Precision System made by Audio Precision in the United States. FIGS. 3A and 3B show comparing results of the noise suppresser to the digital electronic signal. FIG. 3A shows the tested object unequipped with the noise suppresser, and FIG. 3B shows the tested object equipped with the noise suppresser. A computer transmits a digital electronic signal to an MP3 player via a first transmission line and a Universal Serial Bus (USB) (not shown). Thereby, when the digital electronic signal is transmitted to the MP3 player, an analog electronic signal would be generated accordingly. Thereafter, the amplifier amplifies the analog electronic signal and a second transmission line transmits the amplified signal to the audio precision system. Subsequently, a frequency-domain analysis would be conducted in the system. Hence, the analysis is sent back to the computer. The comparing results could be evidently shown in FIG. 3A (the tested object unequipped with the noise suppresser) and FIG. 3B (the USB equipped with the noise suppresser). Obviously, when the noise suppresser of the present invention is applied, the noise magnitude is significantly reduced. To show distinguishing differences between the comparing results, Form 1 is provided for showing the test data in FIG. 3A and FIG. 3B.

Form 1

| | NOISE MAGNITUDE OF | NOISE MAGNITUDE OF |
|---|---|---|
| FRE- | THE OBJECT UN- | THE OBJECT |
| QUENCY | EQUIPPED WITH THE | EQUIPPED WITH THE |
| (HZ) | NOISE SUPPRESSER (dBV) | NOISE SUPPRESSER (dBV) |
| 2K | −72 | −88 |
| 5K | −79 | −92 |
| 13K | −90 | −96 |
| 15K | −82 | −98 |
| 18K | −102 | −108 |

Form 1 presents that when the electronic equipment is equipped with the noise suppresser, the noise magnitude is much less than that of the electronic equipment unequipped with the noise suppresser.

Further, FIGS. 4A and 4B respectively show the comparing results of the noise suppresser of the present invention and the analog electronic signal. Wherein, the analog electronic signal is output by a signal generator of an IEA EA-A Electro-Acoustic Integrated System (made in Italy) via a computer. Further, the analog electronic signal is sent to a circuit via the first transmission line (where the noise suppresser of the present invention is installed). Thereafter, the analog electronic signal is further transmitted back to the IEA EA-Z Electro-Acoustic Integrated System for being analyzed by a joint energy-time-frequency analysis. Afterward, the analyzed data would be sent back to the computer. FIG. 4 shows the tested object unequipped with the noise suppresser of the present invention. Herein, a frequency band is set between 500 and 7000 Hz and the energy is arranged by −41.8 dBV. Relatively, FIG. 4B shows the tested object equipped with the noise suppresser of the present invention. Wherein, even the frequency band is enlarged to 300˜8000 Hz, the energy is still maintained in −43.8 dBV. Obviously, the noise suppresser of the present invention is able to reduce the dynamic energy change, decrease the wasted energy, font improve the clarity of the audio signal (or the audio analog signal).

Accordingly, afore data show that the noise of the circuits or the lines is evidently reduced via the suppression provided by the noise suppresser of the present invention. Thus, the out put sound gets clearer.

Abovementioned preferred embodiments do not limit the spirit and the concept correlated to the present invention. Alike correlations or equivalent embellishments for achieving the same function and purpose of the present invention are deemed not excluded from the scope of the claims.

1. A structure for suppressing noise of electronic equipment comprising electronic equipment wrapped in a zirconia ceramics, which mainly comprises elements of zirconia and at least one oxide that serves as a stabilizer, and said zirconia ceramics being formed by evenly compounding said elements into a compound material and subjecting said compound material to a sintering process process.

2. The structure as claimed in claim 1, wherein, said oxide in said stabilizer adopts calcium oxide, magnesia, yttrium (III) oxide, or compound powder of said elements.

3. The structure as claimed in claim 1, wherein, a weight percentage of said zirconia is between 80 and 99%, and a weight percentage of said stabilizer is between 1 and 20%.

4. The structure as claimed in claim 3, wherein, said stabilizer adopts magnesia.

5. The structure as claimed in claim 3, wherein, said stabilizer adopts calcium oxide.

6. The structure as claimed in claim 3, wherein, said stabilizer adopts yttrium (III) oxide.

7. The structure as claimed in claim 3, wherein, said stabilizer adopts a compound comprising at least two elements from magnesia, calcium oxide, and yttrium (III) oxide.

8. The structure as claimed in claims 1, wherein, said zirconia ceramics adopts a sleeve or a shelter that covers an appearance of said electronic equipment.

9. The structure as claimed in claims 1, wherein, said zirconia ceramics is formed into a flake.

10. The structure as claimed in claims 1, wherein, said zirconia ceramics is formed into a pillar.

11. The structure as claimed in claims 1, wherein, said zirconia ceramics is formed into powder.

12. A method for suppressing noise of electronic equipment, wherein, a structure for suppressing noise being used to shield a surrounding or a surface of said electronic equipment or circuits of said electronic equipment; said structure for suppressing noise of electronic equipment being made by steps of:
preparing a material of zirconia in a proportion of 80 to 99 weight percent;
preparing a material of oxide in a proportion of 1 to 20 weight percent; and
evenly compounding said two materials into a compound material and proceeding to a sintering process for forming said compound material into a zirconia ceramics.

13. The method as claimed in claim 12, wherein, said sintering process sequentially includes a heating stage, a steady temperature stage, and a cooling stage.

14. The method as claimed in claim 13, wherein, in said heating stage, an operating temperature is raised from a room temperature to 1170° C.˜1850° C. within 8 to 14 hours.

15. The method as claimed in claim 13, wherein, in said steady temperature stage, an operating temperature is maintained at a fixed temperature between 1170° C. and 1850° C. for 1 to 4 hours.

16. The method as claimed in claim 13, wherein, in said cooling stage, an operating temperature is cooled from 1170° C.˜1850° C. to a room temperature within 11 to 15 hours.

17. The method as claimed in claims 12, wherein, said compound material is pressed before said sintering process for being formed into a sleeve or a shelter.

18. The method as claimed in claim 15, wherein, said zirconia ceramics subjected to said sintering process is crumbled into powder.
